(19) United States
(12) Patent Application Publication
(10) Pub. No.: US 2015/0095728 A1
(43) Pub. Date: Apr. 2, 2015

(54) TESTING METHOD FOR REDUCING NUMBER OF OVERKILLS BY REPEATEDLY WRITING DATA TO ADDRESSES IN A NON-VOLATILE MEMORY

(71) Applicant: UNITED MICROELECTRONICS CORP., Hsin-Chu City (TW)

(72) Inventors: Hsin-Pang Lu, Hsinchu County (TW); Hsi-Wen Chen, Kaohsiung City (TW); Ya-Nan Mou, Hsinchu City (TW); Chung-Cheng Tsai, Taichung City (TW); Hsiao-Chieh Sung, Hsinchu County (TW); Yin-Ju Hsiao, Hsinchu City (TW)

(73) Assignee: UNITED MICROELECTRONICS CORP., Hsin-Chu City (TW)

(21) Appl. No.: 14/040,752

(22) Filed: Sep. 30, 2013

(51) Int. Cl. G11C 29/00

(52) U.S. Cl. CPC G11C 29/789
USPC 714/721

(57) ABSTRACT

A testing method for non-volatile memory includes writing a first set of data to a set of addresses in a non-volatile memory, reading a second set of data from the set of addresses, and writing the first set of data to the set of addresses again if the first set of data and the second set of data are not identical and number of times for writing the first set of data to the set of addresses is smaller than a predetermined number.

### BACKGROUND OF THE INVENTION

1. Field of the Invention

The present invention discloses a testing method for a non-volatile memory, and particularly, a testing method for reducing number of overkills by repeatedly writing data to addresses in the non-volatile memory.

2. Description of the Prior Art

Non-volatile memory such as flash memory, OTPROM (One-time programmable ROM), MTPROM (Multiple-time programmable ROM) and EEPROM (Electrically-Erasable Programmable Read-Only Memory) is widely adopted in many kinds of consumer electronics for storing data without power being supplied. When performing a pre-wafer-dicing circuit probing test (hereinafter referred to as “CP test”) on one of a batch of newly produced non-volatile memories on a wafer, it is necessary to write data to an address in the non-volatile memory so as to make a memory cell corresponding to the address develop correct feature when it stores a logic 0 or 1. The mentioned correct feature means that, for example, an ideal non-volatile memory cell should have a cell current close to 0 uA when it stores a logic 0 and a cell current close to 40 uA when it stores a logic 1.

If every memory cell in a newly produced non-volatile memory is initially stored a logic 1, it is necessary to write a logic 0 to the memory cell in the non-volatile memory while performing a CP test so as to make a cell current of each memory cell be read a correct value corresponding to a low logic level, that is a cell current close to 0 uA. This step is to perfect the function of the memory cell. Without writing a logic 0 during the CP test, a correct cell current corresponding to a logic 0 can not be measured from the memory cell when it stores a logic 0 afterward. Likewise, if all memory cells of a newly produced non-volatile memory store logic 0s, writing logic is in the non-volatile memory during a CP test is also necessary to perfect function of the memory cells.

When reading a non-volatile memory cell, because data stored in the memory cell is determined to be a logic 1 or 0 by measuring a cell current of the memory cell, a current threshold is required. When the number of measured memory cells is large enough, a statistical curve can be drawn from the memory cells, and the number of memory cells can be observed to be close to a normal distribution with respect to the cell current. A memory designer can determine a current threshold according to a statistical analysis and professional considerations. The current threshold is used to determine the value of data stored in a memory cell of a non-volatile memory: if measured cell current is larger than the current threshold, the value of data stored in the memory cell is determined to be a logic 1. If measured cell current is smaller than the current threshold, the value of data stored in the memory cell is determined to be a logic 0.

Please refer to FIG. 1. FIG. 1 shows a distribution of number of memory cells with respect to cell current. The horizontal axis refers to cell current, and the vertical axis refers to number of memory cells. The group of memory cells distributed on the left part of FIG. 1 corresponding to smaller than 5 uA cell current are memory cells each storing a logic 0. The other group of memory cells distributed on the right part of FIG. 1 corresponding to about 35˜50 uA cell current are memory cells each storing a logic 1. A memory designer can determine a current threshold such as 20 uA according to statistical result from real measurement as shown in FIG. 1 and professional considerations.

Please refer to FIG. 2. FIG. 2 shows a flowchart of performing a prior art CP test for testing a non-volatile memory. The steps of the method are as follows:

Step 201: Write a first set of data to a set of addresses in a non-volatile memory;

Step 202: Read a second set of data from the set of addresses after writing the first set of data to the set of addresses;

Step 203: Check if the first set of data and the second set of data are identical; if so, go to Step 204; if not, go to Step 205;

Step 204: Determine the non-volatile memory has passed the test, go to Step 206;

Step 205: Determine the non-volatile memory has failed the test, go to Step 206;

Step 206: Exit.

However, after adopting the prior art CP test, the yield of the non-volatile memories seems quite low. The reason is that cell currents of part of memory cells in a newly produced non-volatile memory can not be measured to be smaller than the current threshold after writing data of logic Os to those memory cells . Hence, a solution is necessary to overcome the low yield issue in the prior art.

### SUMMARY OF THE INVENTION

An embodiment of the present invention discloses a testing method for testing a non-volatile memory. The testing method comprises writing a first set of data to a set of addresses in the non-volatile memory, reading a second set of data from the set of addresses after writing the first set of data to the set of addresses, and writing the first set of data to the set of addresses again if the first set of data and the second set of data are not identical.

Another embodiment of the present invention discloses a testing method for testing a non-volatile memory. The testing method comprises writing a first set of data to a set of addresses in the non-volatile memory, reading a second set of data from the set of addresses after writing the first set of data to the set of addresses, and writing the first set of data to the set of addresses again if the first set of data and the second set of data are not identical and number of times for writing the first set of data to the set of addresses is smaller than a predetermined number.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a distribution of number of memory cells with respect to cell current.

FIG. 2 is a flowchart of performing a prior art CP test for testing a non-volatile memory.

FIG. 3 is a flowchart of performing a CP test according to an embodiment of the present invention.

FIG. 4 is a timing diagram of performing the CP test in FIG. 3.

FIG. 5 is a flowchart of integrating the CP test in FIG. 3 with a reliability test.

FIG. 6 shows distributions of number of memory cells with respect to cell current before and after non-volatile memories are baked.

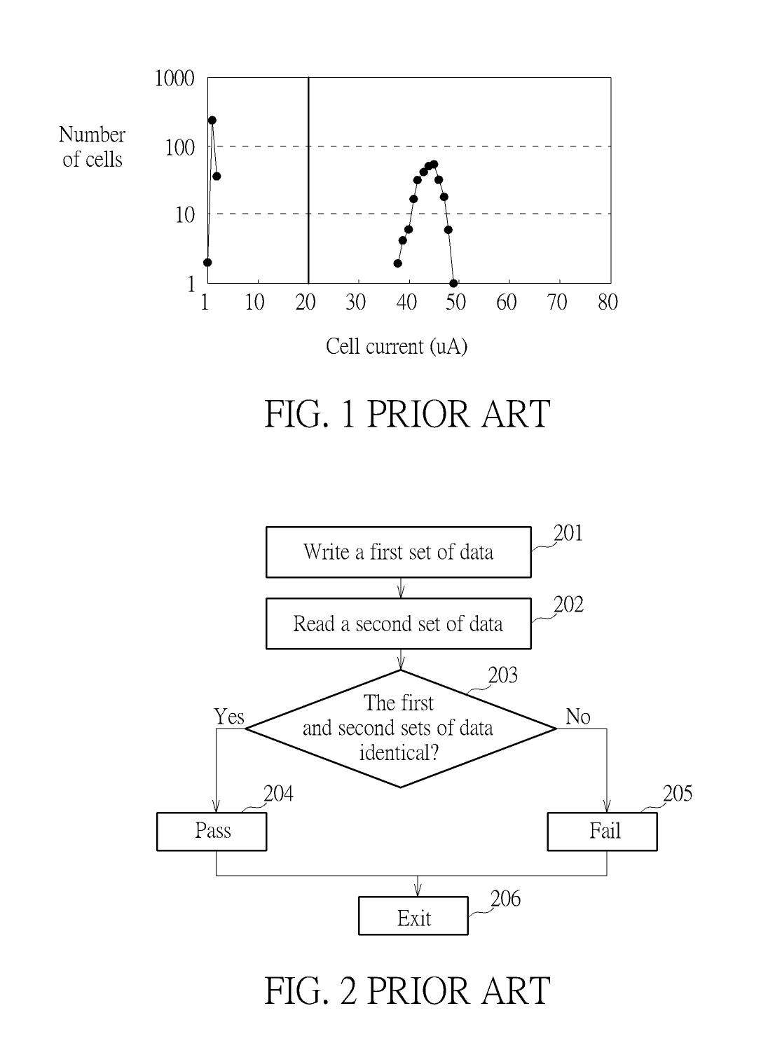

### DETAILED DESCRIPTION

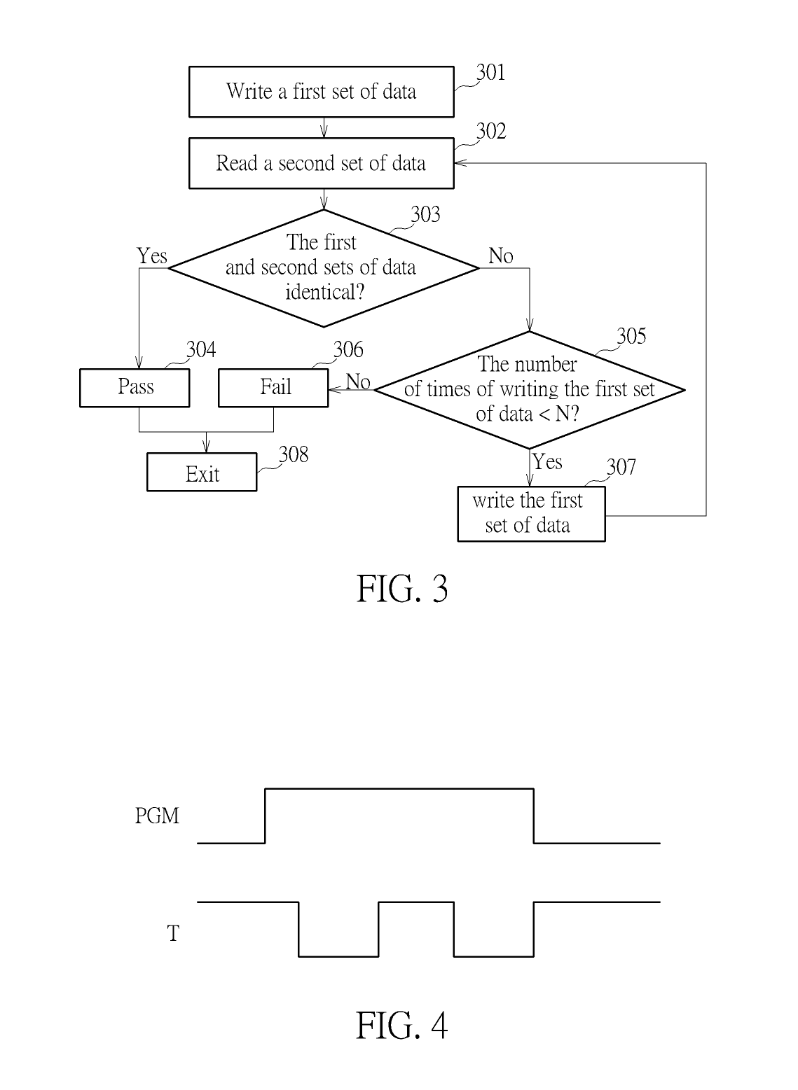

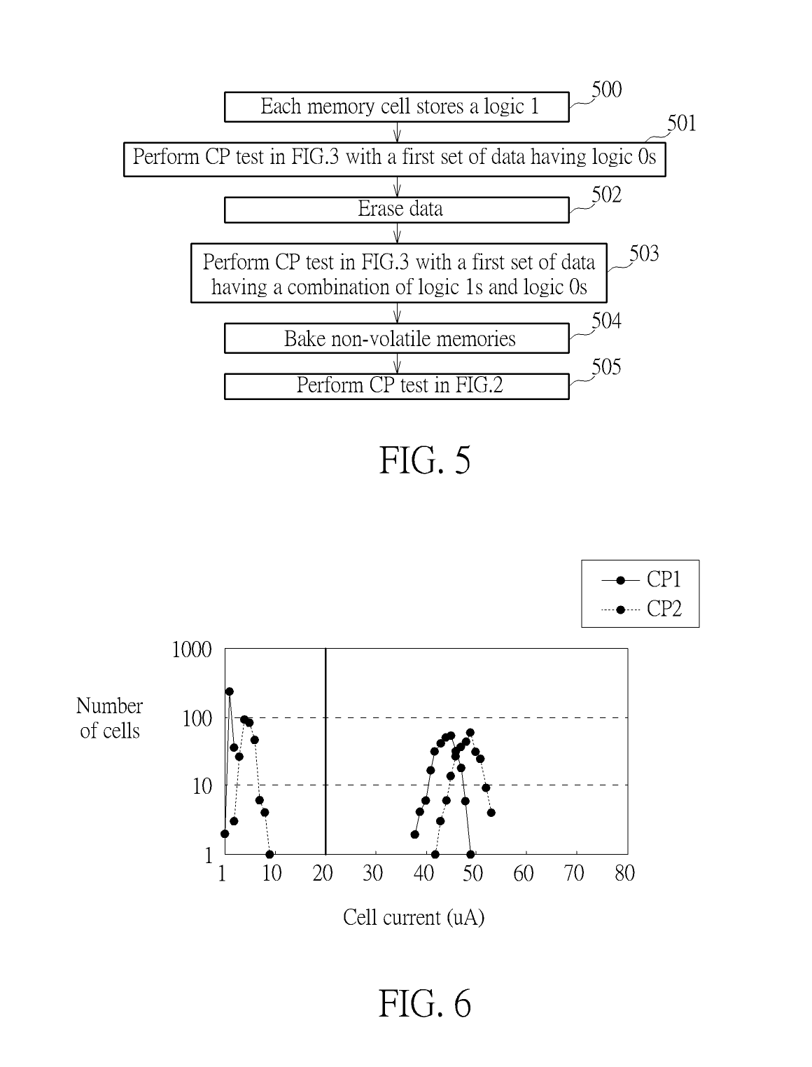

Please refer to FIG. 3. FIG. 3 shows a flowchart of performing a CP test according to an embodiment of the present invention. The steps of the flowchart are as follows:

Step 301: Write a first set of data to a set of addresses in a non-volatile memory;

Step 302: Read a second set of data from the set of addresses after writing the first set of data to the set of addresses;

Step 303: Check if the first set of data and the second set of data are identical; if so, enter Step 304; if not, enter Step 305;

Step 304: Determine the non-volatile memory has passed the test, go to Step 308;

Step 305: Check if the number of times of writing the first set of data to the set of addresses is smaller than a predetermined number N; if so, go to Step 307; if not, go to Step 306;

Step 306: Determine the non-volatile memory has failed the test, go to Step 308;

Step 307: write the first set of data to the set of addresses for a predetermined length of time; go to Step 302;

Step 308: Exit.

The first set of data in Step 301 can be a 16-bit data which can be all-0 data, all-1 data, or a combination of 0s and 1s. The set of addresses can be a set of addresses corresponding to 16 memory cells. The CP test disclosed by the present invention is for newly produced non-volatile memories on a wafer without being wafer-diced, and values of corresponding bits of the first set of data should be complementary to original data stored in the set of addresses. For example, if each memory cell in a newly produced non-volatile memory stores a logic 1, the first set of data should contain all-0 so as to make each memory cell develop a correct feature when it stores a logic 0 after a logic 0 is written to the memory cell. The correct feature of a non-volatile memory cell when it stores a logic 0 corresponds to a cell current measured to be smaller than a current threshold. When performing the check step in Step 303, if the second set of data and the first set of data are not identical, it is further checked to see if the number of times of writing the first set of data to the set of addresses is smaller than a predetermined number N in Step 305. If the number of times of writing the first set of data to the set of addresses is smaller than the predetermined number N, the first set of data is written to the set of addresses again for a predetermined length of time in Step 307, and then Step 302 and certain following steps are performed again to check if the read second set of data are identical to the first set of data written in Step 307. By repeatedly writing the first set of data to the set of addresses for at most N times, some non-volatile memory cells in the set of addresses without correct feature after being written just once can be modified to have a correct feature.

For example, if the first set of data is a set of 16-bit all-0 data, cell currents measured from 16 non-volatile memory cells are not all smaller than a current threshold after writing 16-bit all-0 data to a set of addresses corresponding to the 16 non-volatile memory cells, and number of times for writing the first set of data to the set of addresses is smaller than a predetermined number N in Step 305, Step 307 is performed to write 16-bit all-0 data again to the set of addresses so as to change the feature of the 16 non-volatile memory cells, that is, to make each of the 16 non-volatile memory cells with a cell current smaller than the current threshold when it stores a logic 0. The mentioned predetermined number N in Step 305 is decided by non-volatile memory designers according to statistical data from experiments and professional experiences. Take N=3 as an example, N=3 means that if a cell current measured from a non-volatile memory cell is not smaller than a current threshold after the non-volatile memory cell being written with a logic 0 for three times, the non-volatile memory cell is determined to have failed the test. The mentioned predetermined length of time in Step 307 is determined by non-volatile memory designers according to statistical data from experiments and professional experiences. The predetermined length of time in Step 307 can be 160 us. If the predetermined length of time in Step 307 is too long, testing time is increased, and test cost of time and money is increased accordingly because testing vendors usually charge according to testing time. If the predetermined length of time in Step 307 is too short, the feature of non-volatile memory cells might not be modified correctly.

Please refer to FIG. 4 in addition to FIG. 3. FIG. 4 shows a timing diagram of performing the CP test in FIG. 3. In FIG. 4, a test mode control signal PGM and an internal timing control signal T are shown. The test mode control signal PGM has a high level when performing the CP test in FIG. 3, and has a low level when the CP test in FIG. 3 is not performed. The internal timing control signal T has a high level when writing data to a set of addresses in the non-volatile memory, and has a low level when reading data from the set of addresses in the non-volatile memory and when checking if the written data and read data are identical. According to FIG. 4 and FIG. 3, after the test mode control signal PGM is switched from the low level to the high level, Step 301 is performed to write a first set of data to the set of addresses in the non-volatile memory. Then Step 302 is performed to read a second set of data from the set of addresses. The first and second sets of data are checked to see if the two sets of data are identical. Since they are not identical, the first set of data is written to the set of addresses again for a predetermined length of time. And a third set of data stored in the set of addresses is read from the set of addresses to check if the first and third sets of data are identical. Since in FIG. 4's example, the first and third sets of data are identical. The test mode control signal PGM is switched from the high level to the low level.

Compared with the prior art CP test, the CP test in FIG. 3 can help a part of non-volatile memory cells which could not pass the CP test after being written just once to pass the CP test by modifying the feature of the memory cells more than once.

In the CP test of FIG. 3, the value of each bit of the first set of data can be adjusted according to application requirements. And the CP test can further be combined with a reliability test as follows and as shown in FIG. 5 to make the test for non-volatile memory more complete:

Step 500: Before testing a plurality of non-volatile memories on a wafer without being diced, each memory cell of the non-volatile memories stores a logic 1;

Step 501: Test the non-volatile memories by following the CP test in FIG. 3 with a first set of data having a logic value in each bit being 0;

Step 502: Erase data stored in non-volatile memories passing the CP test of Step 501 so as to write a logic 1 into each memory cell of the non-volatile memories passing the CP test of Step 501;

Step 503: Test the non-volatile memories erased in Step 502 by following the CP test in FIG. 3 with a first set of data having a combination of logic is and logic 0s;

Step 504: Bake non-volatile memories passing the CP test in Step 503 at 250° C. for 24 hours;

Step 505: Test the non-volatile memories after being baked in Step 504 by following the prior art CP test in FIG. 2.

In Step 502, the value of erased data in each of the non-volatile memory cells is a logic 1 because the memory cells of the non-volatile memories have initial values of logic 1s. If the initial values are logic 0s, then the value of erased data in each of the non-volatile memory cells would be a logic 0. In Step 503, the first set of data has a combination of logic is and logic 0s so as to perform a “checker-board” memory test. The “checker-board” memory test can evaluate if unwanted crosstalk and memory fault would occur when memory cells of a non-volatile memory containing logic is and logic 0s are arranged alternatively in a memory array. Further the checker-board memory test can check if memory cells have correct feature when storing logic 1s. Step 504 is used to verify reliability of aging non-volatile memories. Please refer to FIG. 6. FIG. 6 shows distributions of number of memory cells with respect to cell current before and after Step 504 is performed. The horizontal axis refers to cell current, and the vertical axis refers to number of memory cells. In FIG. 6, memory cells distributed on the left part of FIG. 6 corresponding to smaller than 20 uA cell current each store a logic 0, and memory cells distributed on the right part of FIG. 6 corresponding to greater than 20 uA cell current each store a logic 1. The curves CP1 drawn in solid lines show the distribution measured before the non-volatile memories are baked. The curves CP2 drawn in broken lines show the distribution measured after the non-volatile memories are baked. 20 uA is a current threshold determined by non-volatile memory designers according to a statistical analysis and professional considerations. According to FIG. 6, after baking, the cell current of each non-volatile memory cell increases when the non-volatile memory cell stores either a logic 1 or a logic 0. For example, part of non-volatile memory cells are measured with cell currents smaller than a current threshold such as 20 uA when storing logic 0s before being baked so that their corresponding non-volatile memory is determined to pass the CP test in Step 503. However, after being baked, some of the memory cells stored logic 0s before being baked have their cell currents increased to be above the current threshold such as 20 uA. This makes their corresponding non-volatile memory fail the reliability test under 250° C. for 24 hours in Steps 504 and 505. Step 504 and Step 505 are of a High temperature baking reliability test, also known as “aging” test because the baking accelerates the aging of non-volatile memories. The mentioned aging test with 250° C. for 24 hours is an example, and users can adopt other conditions by modifying factors such as temperature, operating voltage, pressure and duration of exposure for reliability test according to applications of non-volatile memories.

When adopting the CP test of prior art shown in FIG. 2, low yield issue often occurs even before reliability test is performed, and the low yield issue deteriorates after the following reliability test is performed. In order to solve the low yield issue, overkill analysis and related debugging are performed, wasting the resource of research and development in debugging. Hence, by adopting the CP test disclosed by the embodiment of the present invention, number of overkills occurring at early stage before performing the reliability test can be effectively reduced, improving the yield of the non-volatile memories and reducing the amount of overkill analyses and debugging.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A testing method for testing a non-volatile memory comprising:
writing a first set of data to a set of addresses in the non-volatile memory;
reading a second set of data from the set of addresses after writing the first set of data to the set of addresses; and
writing the first set of data to the set of addresses again if the first set of data and the second set of data are not identical.

2. The method of claim 1 further comprising:
reading a third set of data after writing the first set of data to the set of addresses again.

3. The method of claim 2 further comprising erasing data stored in the set of addresses if the first set of data and the third set of data are identical.

4. The method of claim 1 wherein values of corresponding bits of the first set of data and original data stored in the set of addresses are complementary.

5. The method of claim 4 wherein a value of each bit of the first set of data is 0, and a value of each bit of the original data is 1.

6. The method of claim 4 wherein a value of each bit of the first set of data is 1, and a value of each bit of the original data is 0.

7. The method of claim 1 wherein reading the second set of data from the set of addresses is reading the second set of data from the set of addresses by reading cell currents corresponding to the set of addresses.

8. The method of claim 7 further comprising setting a current threshold for determining bit values of the second set of data.

9. The method of claim 1 further comprising setting a length of time for performing writing the first set of data to the set of addresses.

10. A testing method for testing a non-volatile memory comprising:
writing a first set of data to a set of addresses in the non-volatile memory;
reading a second set of data from the set of addresses after writing the first set of data to the set of addresses; and
writing the first set of data to the set of addresses again if the first set of data and the second set of data are not identical and number of times for writing the first set of data to the set of addresses is smaller than a predetermined number.

11. The method of claim 10 further comprising:
reading a third set of data after writing the first set of data to the set of addresses again.

12. The method of claim 11 further comprising erasing data stored in the set of addresses if the first set of data and the third set of data are identical.

13. The method of claim 10 wherein values of corresponding bits of the first set of data and original data stored in the set of addresses are complementary.

14. The method of claim 13 wherein a value of each bit of the first set of data is 0, and a value of each bit of the original data is 1.

15. The method of claim 13 wherein a value of each bit of the first set of data is 1, and a value of each bit of the original data is 0.

16. The method of claim 10 wherein reading the second set of data from the set of addresses is reading the second set of data from the set of addresses by reading cell currents corresponding to the set of addresses.

17. The method of claim 16 further comprising setting a current threshold for determining bit values of the second set of data.

18. The method of claim 10 further comprising setting a length of time for performing writing the first set of data to the set of addresses.
